(19) United States
(12) Patent Application Publication
(10) Pub. No.: US 2006/0290364 A1
(43) Pub. Date: Dec. 28, 2006

(54) Cable terminal with flexible contacts

(76) Inventor: Dan DeLessert, Newburg, OR (US)

Correspondence Address: LANGLOTZ PATENT WORKS, INC., PO BOX 759, GENOA, NV, 89411, US

(21) Appl. No.: 11/512,553

(22) Filed: Aug. 29, 2006

Related U.S. Application Data
(63) Continuation of application No. 10/965,425, filed on Oct. 13, 2004, now abandoned.

(51) Int. Cl. G01R 31/02

(52) U.S. Cl. 324/754

(57) ABSTRACT

A cable assembly connector has a body with a number of contact elements connected to the body. Each of the contact elements is an elongated conductor formed into a serpentine shape, and has a contact end portion protruding from the body. The contact end portion of each contact element includes a curved portion having a convex surface facing away from the body, and a free end of each contact end portion is recurved toward the body. The connector may include a planar circuit element connected to the rear end portions of the contact elements, and a flexible cable may be connected to the connector. The connector may be employed in a method of testing a printed circuit assembly having an exposed contact array at a position away from the edge of the printed circuit assembly by aligning the contact elements of the connector with the contact array, pressing the terminal against the contact array, and transmitting a signal via the cable from the contact array to an instrument connected to the flexible cable.

### REFERENCE TO RELATED APPLICATION

This is a continuation of application Ser. No. 10/965,425, filed Oct. 13, 2004.

### FIELD OF THE INVENTION

This invention relates to electrical cables and connectors, and more particularly to probes for testing contact points on printed circuit assemblies.

### BACKGROUND OF THE INVENTION

Probes are employed in the process of testing electronic devices and components. Such devices operate at high frequencies that require a design sensitive to signal management. Similarly, probes for testing such devices must be capable of carrying signals at high frequencies to avoid degrading a signal that is to be analyzed. Conventional probes for testing high-frequency devices employ spring pins that have elongated pins that reciprocate within sleeves. These function effectively at high frequencies, and provide a long travel distance with a limited force, but are costly to manufacture, especially for applications requiring an array of numerous contacts for simultaneously probing multiple locations.

In addition, many conventional probes employ axial contacts that do not always provide a positive ohmic contact, due to oxides or other contaminants that may be present in a thin layer on the metal surfaces of the device to be probed. Probes with elongated needle-like pins are particularly unsuited for any scrubbing or skating motion to break through any such film, and may generate unwanted wear or damage of the probe or the device is such motion is attempted.

When circuit boards having mounted electronic components are being tested, conventional testing employs edge connectors on the board, which are metal strips at the termination of conductive traces on the board. However, this has several disadvantages, in that the edge connectors occupy significant board area, and are not necessarily located between certain interacting components with intermediate nodes that are critical for testing.

Existing probes requiring high frequency capabilities are typically supported on circuit boards that include the electronic components for processing and testing the signals of the device. Accordingly, such probe configurations are cumbersome, and make access to all parts of the device difficult. Moreover, such probe configurations do not allow operators or machine vision systems to readily observe the location of contact to ensure alignment, making more expensive robotic alignment systems necessary.

### SUMMARY OF THE INVENTION

The present invention overcomes the limitations of the prior art by providing a cable assembly connector having a body with a number of contact elements connected to the body. Each of the contact elements is an elongated conductor formed into a serpentine shape, and has a contact end portion protruding from the body. The contact end portion of each contact element includes a curved portion having a convex surface facing away from the body, and a free end of each contact end portion is recurved toward the body. The connector may include a planar circuit element connected to the rear end portions of the contact elements, and a flexible cable may be connected to the connector. The connector may be employed in a method of testing a printed circuit assembly having an exposed contact array at a position away from the edge of the printed circuit assembly by aligning the contact elements of the connector with the contact array, pressing the terminal against the contact array, and transmitting a signal via the cable from the contact array to an instrument connected to the flexible cable.

### BRIEF DESCRIPTION OF THE DRAWINGS

FIG. 1 is a perspective view of a cable assembly and associated devices according to a preferred embodiment of the invention.

FIG. 2 is an enlarged sectional side view of a cable terminal of FIG. 1.

FIG. 3 is a perspective view of a printed-circuit based probe according to an alternative embodiment of the invention.

FIG. 4A is a plan view of a contact according to the embodiment of FIG. 1.

FIG. 4B is a side view of a contact according to the embodiment of FIG. 1.

### DETAILED DESCRIPTION OF A PREFERRED EMBODIMENT

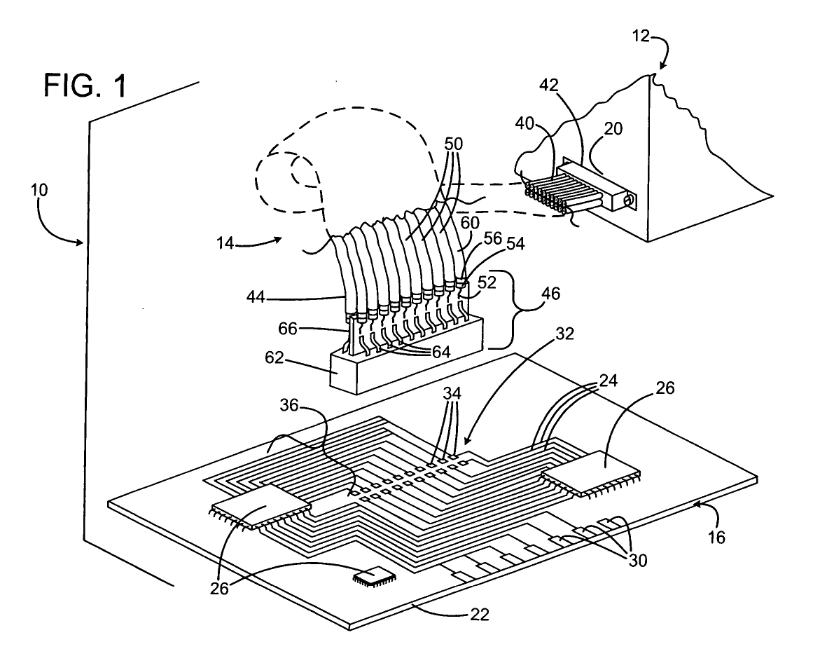

FIG. 1 shows an electronic probing and testing system 10 including an electronic test instrument or computer 12, a cable assembly 14 connected to and extending from the instrument, and a device under test such as a printed circuit assembly 16. The instrument 12 is a conventional high speed digital oscilloscope, logic analyzer, or other such device used for testing high speed digital or analog circuitry, and has a connector port 20 with multiple contacts connected to internal circuitry that analyzes the signal so that it can be viewed on an instrument display.

The device under test may be any electronic device. In the illustrated embodiment, the device is a printed circuit board 22 that is printed with a pattern of conductive traces 24, and upon which are mounted a number of electronic components 26 such as integrated circuits. The components are electrically connected to arrays of conductive pads on the board, and interconnected via traces on the board (not all of which are shown.) The board may include interface connections such as edge connector strips 30, which are connected to the circuitry, and exposed for connection when the board is eventually installed in an electronic assembly of which it is a component. The board may be provided with a retention facility (not shown) that removably receives a housing of a probe assembly discussed below. Such a facility may be fastened to the board by screws, snap elements, solder, or other means, and would provide a mechanical receptacle for receiving, aligning, and securing the probe housing.

The device under test includes a mid-bus pad array 32. The array is a plurality of exposed conductive pads 34, each of which is connected to only a single trace on a bus 36 that provides connections among at least two components or connectors. In alternative embodiments, the array may be positioned on traces between one or more components and the edge or other connectors. In any event, the array is positioned away from the edge of the board, not accessible to connectors that would be suitable for contacting edge contacts. By probing at a mid-bus location, the probe has access to lines that never reach external connectors, so that the signal on a line between components can be analyzed to determine performance, errors, or other characteristics. The array may be of any configuration to be compatible with a test probe as noted below, but in the preferred embodiment is a pair of rows of pads in a dual-in-line configuration, with the rows spaced apart by 0.050 inch, and the pads aligned on 0.100 inch center-to-center spacing. In the preferred embodiment, the pads are arrayed in two rows of 27 pads, although any number of rows from one to three or more may be employed in alternative embodiments.

The cable assembly 14 has a first end 40 with a first connector 42 that is removably mated with the instrument's connector port 20. The cable assembly has an opposed free end 44 that includes a terminal assembly 46 that will be discussed in detail below. The cable includes a ribbon of wires 50 arranged in a flat ribbon, with the wires in a close arrangement so that the wires are adjacent to each other. In the preferred embodiment, for two rows of test pads to be addressed, the cable has two flat ribbons, one for each row.

Each wire is a coaxial wire having a central conductor 52 surrounded by a dielectric layer 54. A conductive shield 56 of foil or wound wire strands surrounds the dielectric layer, and an insulating jacket 60 surrounds the shield. In the preferred embodiment, the central conductor is 34 gauge, with the dielectric having a thickness of 0.024 inch. The shield and jacket bring each wire to a 0.041 inch overall diameter. In alternative embodiments, the wire's parameters may be adjusted to provide the desired performance, with consideration given to the mechanical limitations of the connector contact spacing.

The terminal assembly 46 includes a plastic housing or block 62, a set of spring contact elements 64 secured within and partially protruding from the body, and a printed circuit element 66 electrically connected to the contact elements and to the ends of the wires.

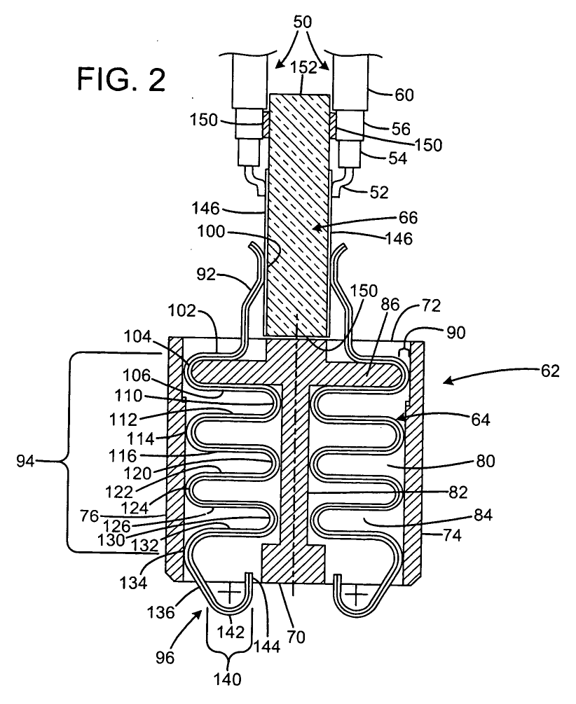

Referring to FIG. 2, the block 62 is a rectangular body having a front face 70, rear face 72, major elongated side faces 74, 76, and end faces (shown in FIG. 1.) The block defines a number of passages 80 extending from the front face to the rear face, one for each of the conductive elements. The rows of passages are separated from each other in one direction by a medial septum 82 that extends the length of the block from end to end, from front face 70 to rear face 72, and oriented parallel to and equidistant from the major side walls 74 and 76. The passages are separated from adjacent passages in the same row by divider walls 84. Thus, each passage is defined by the medial septum, a side wall 74 or 76, and a pair of divider walls 84 (except the endmost passages which are defined by the end walls of the block.) Within each passage near the rear face, a shelf 86 extends laterally from the medial septum 83, spanning between the divider walls, leaving only a small gap 90 where the nose of the shelf approaches the inner surface of the side wall 74 or 76.

A spring contact element 64 is received within each passage 80 of the block. Each spring is an elongated flat strip of constant width, formed into an articulated shape with a series of bends and curves, each made about an axis parallel to the plane of the strip. Thus, when formed to the shape shown, the major edges of the strip each occupy a respective plane. The spring has a rear end portion 92 protruding generally perpendicularly from the rear face of the block 62, an articulated intermediate portion 94, and an arcuate contact portion 96. The rear portion has a rear contact surface 100 that faces medially. The intermediate portion is a serpentine shape having a number of semicircular hairpin bends with straight segments connecting the bends. The straight segments are generally parallel to the front face, which is the axial direction of terminal motion to make contact with a contact array.

The spring includes a first limited-length straight segment 102, a first bend 104 concave in the medial direction and connected to the first segment, a second straight segment 106 connected to the first bend, a second laterally concave bend 110 connected to the second segment. The serpentine progression continues with segment 112, bend 114, segment 116, bend 120, segment 122, bend 124, segment 126, bend 130, and segment 132. A bend 134 is connected to the segment 132, and arcs about 120 degrees, so that a connected segment 136 extends in an angled direction that passes through the plane defined by the face 70 of the block. An arcuate contact portion 140 is recurved back toward the block, convex away from the block with a convex contact surface 142 having a tangent surface portion parallel to the block face 70. A straight end segment 144 extends axially back through the plane of the face 70, and partially into the passage 80. Accordingly, of the arcuate contact portion, only an intermediate portion protrudes from the block, so that there are no exposed ends beyond the face of the block that could catch on devices under test.

The spring is secured within its respective passage of the block by the shelf 86 being tightly received between segments 102 and 106, with the nose of the shelf being closely encompassed by bend 104. The spring operates under axial pressure applied to the contact surface 142 by flexing of the bends and straight segments, with a spring force that does not increase significantly over the entire displacement of the contact portion to a fully depressed position in which it is at the plane of the face 70. Bends 110, 114, 120, 124, 126, and 134 are free to flex under force, with the equal number of each direction bend generating a balance of forces so that the spring responds to an axial force on the contact surface 142 with nearly axial motion, as with a coil spring. The straight portions further flex as leaf springs to provide added flexibility.

During flexure, the motion of a point on the contact portion is not perfectly straight, but is slightly arcuate due to the geometry of the adjacent bend 134. This provides a slight scrubbing of the contact on a pad upon which it is pressed. However, this scrubbing is very limited by the balanced geometry of the several alternating actuate bends, so that the scrubbing is only slight, avoiding needles wear or damage. Similarly, wear is limited because the contact surface is a smooth convex arc, and the spring's free end is recessed as noted above.

In the preferred embodiment, the spring is formed of BeCu material, with a thickness of 0.005 inch, a strip width of 0.015 inch, and a strip length of 0.220 inch. These parameters may be varied to provide needed performance characteristics.

If the contacts are placed at the correct spacing, the electrical reactive impedance can be varied. By varying the reactive impedance, coupling between contacts may be minimized for single ended impedance configurations. By varying the reactive impedance, coupling may be maximized for differential impedance configurations.

The printed circuit element 66 is a double-sided board with an array of signal contacts 146 on each side, the contacts in the arrays being electrically isolated from each other, and arranged with a spacing the same as the spacing of the spring contacts. Each signal contact 146 is an elongated strip, oriented perpendicular to the long axis of the board's leading edge 150, which abuts the rear surface 72 of the block. An elongated ground contact 150 is located on each side of the board, along the entire length of the rear edge 152. Each coax cable 50 is electrically and mechanically connected by solder joints to the pads. Each central conductor 52 is soldered to a respective contact 146, and each shield is connected to contact 150. The surfaces 100 of the springs' rear portions 92 are similarly soldered to the forward portions of the contacts 146.

The system operates for testing the device by aligning the contact elements of the terminal with the contact array on the device, pressing the terminal against the contact array; and transmitting a signal via the cable from the contact array to the instrument via the flexible cable. The contact array is located at an intermediate position on the electrical bus to provide access to lines not otherwise accessible to the device connectors, and I the process of pressing the terminal, the leaf springs in the terminal are flexed. Contact is made by the convex portions of the springs, providing a broad area of contact without risk of damage to device plating.

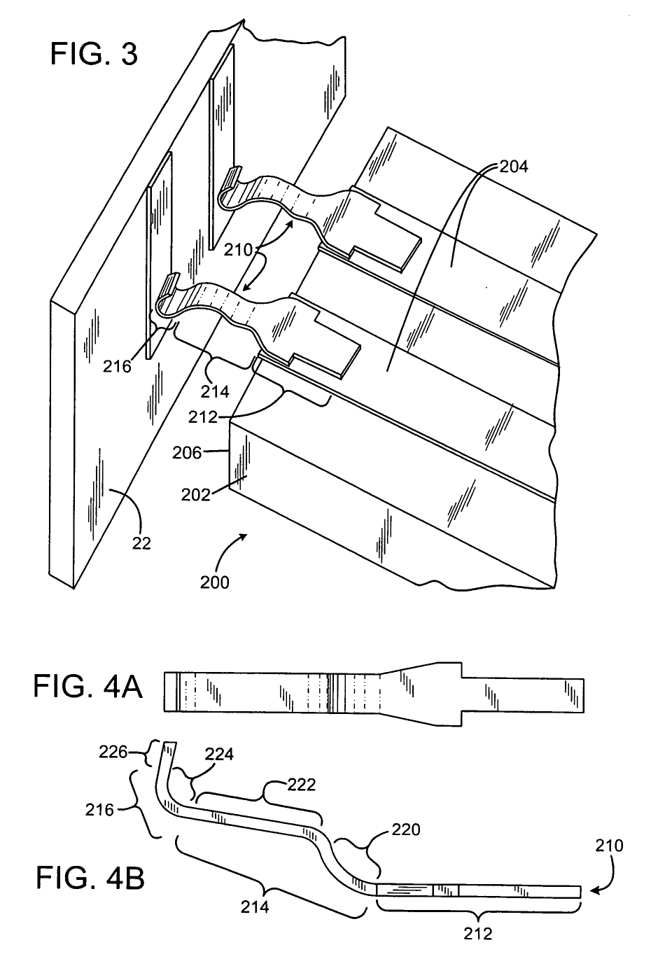

FIG. 3 shows an alternative probe configuration in which a device under test 22 is probed by an alternative probe assembly 200. The probe assembly includes a printed circuit board 202 having an array of exposed conductive pads 204. The pads are connected to traces that connect via cable or other conductor to the test instrument, and are located at a free edge 206 of the board.

A leaf-spring contact 210 is soldered to each pad. Each contact is formed of a sheet of BeCu material with a thickness of 0.005. The contact is curved as will be described below, with all curves being about axes that are perpendicular to the length of the contact. As shown in FIG. 4A and 4B, the contact has a flat base portion 212 overlaying the pad, an articulated intermediate portion 214, and a curved end portion 216. As shown in FIG. 4, the contact has an articulated shape. The intermediate portion includes an upwardly curved portion 220 adjacent to the base portion 212. The curved portion curves upward through an arc of about 60 degrees, to an elevation above the flat portion of about 0.020 inch. The intermediate portion than sharply bends I the opposite direction, and continues as a straight portion 222 angled slightly upward by 10 degrees with respect to the base portion. At the end of the straight portion, the end portion curves through an arc 224 of 90 degrees, with a radius of about 0.010. A terminal end portion 226 extends straight from the end of the arc, and points upward and slightly back toward the base portion, at an angle of 80 degrees to the base portion.

As with the initial embodiment discussed above, the articulated shape of the intermediate portion permits flexing in response to axial force. The curved end portion with the end portion that extends back away from a surface being contacted prevents damaging friction, and enables slight scrubbing of a surface being contacted by the contact without scraping by exposed corners or edges.

While the above is discussed in terms of preferred and alternative embodiments, the invention is not intended to be so limited.

1. A connector comprising:
a body defining a plane and having a peripheral edge;
a plurality of contact elements each having a first portion overlaying and connected to the body;
each of the contact elements having a second portion extending away from the body, beyond the peripheral edge;
each of the contact elements being an elongated conductor;
the second portion of each contact element being formed into an articulated shape;
the second portion of each contact element having a free end including a curved portion having a convex surface facing away from the body; and
a free end of each contact end portion being recurved toward the body.

2. The connector of claim 1 wherein the contact element is a leaf spring.

3. The connector of claim 1 wherein the articulated shape includes a first bend that is convex in a first direction and a second bend that is convex in a second direction.

4. The connector of claim 1 wherein the body includes conductive traces to which each of the first portions is connected electrically and mechanically.

5. The connector of claim 4 wherein each of the first portions overlays a corresponding trace.

6. The connector of claim 1 wherein the body defines a major plane, and wherein the end portion has a contact surface perpendicular to the major plane.

7. The connector of claim 1 wherein the end portion has a cylindrical surface facing away from the body.

8. A connector comprising:
a body defining a plane and having a peripheral edge;
a plurality of contact elements each having a first portion overlaying and connected to the body;
each of the contact elements having a second portion extending away from the body, beyond the peripheral edge;
each of the contact elements being an elongated conductor;
the second portion of each contact element being formed into an articulated shape;
the second portion of each contact element having a free end including a curved portion having a convex surface facing away from the body; and
a free end of each contact end portion having a cylindrical surface facing away from the body.

9. The connector of claim 8 wherein the contact element is a leaf spring.

10. The connector of claim 8 wherein the articulated shape includes a first bend that is convex in a first direction and a second bend that is convex in a second direction.

11. The connector of claim 8 wherein the body includes conductive traces to which each of the first portions is connected electrically and mechanically.

12. The connector of claim 11 wherein each of the first portions overlays a corresponding trace.

13. The connector of claim 8 wherein the body defines a major plane, and wherein the end portion has a contact surface perpendicular to the major plane.

14. The connector of claim 8 wherein the end portion has a cylindrical surface facing away from the body.

15. A connector comprising:
a body defining a plane and having a peripheral edge;
a plurality of contact elements each having a first portion overlaying and connected to the body;
each of the contact elements having a second portion extending away from the body, beyond the peripheral edge;
each of the contact elements being an elongated conductor;
the second portion of each contact element being formed into an articulated shape including a first bend that is convex in a first direction and a second bend that is convex in a second direction;
the second portion of each contact element having a free end including a curved portion having a convex surface facing away from the body; and
a free end of each contact end portion being having a convex surface facing away from the body.

16. The connector of claim 15 wherein the contact element is a leaf spring.

17. The connector of claim 15 wherein the articulated shape includes a first bend that is convex in a first direction and a second bend that is convex in a second direction.

18. The connector of claim 15 wherein the body includes conductive traces to which each of the first portions is connected electrically and mechanically.

19. The connector of claim 18 wherein each of the first portions overlays a corresponding trace.

20. The connector of claim 15 wherein the body defines a major plane, and wherein the end portion has a contact surface perpendicular to the major plane.
